(19) United States
(12) Patent Application Publication
(10) Pub. No.: US 2014/0255832 A1
(43) Pub. Date: Sep. 11, 2014

(54) HARDCOAT COMPOSITIONS

(71) Applicant: 3M INNOVATIVE PROPERTIES COMPANY, St. Paul, MN (US)

(72) Inventor: Zai-Ming Qiu, Woodbury, MN (US)

(21) Appl. No.: 14/350,481

(22) PCT Filed: Oct. 17, 2012
(86) PCT No.: PCT/US2012/060569

§ 371 Date: Apr. 8, 2014

Related U.S. Application Data
(60) Provisional application No. 61/549,138, filed on Oct. 19, 2011.

(51) Int. Cl. C09D 183/06; G03F 1/00

(52) U.S. Cl. CPC C09D 183/06; G03F 1/00
USPC 430/5; 524/868; 523/435

(57) ABSTRACT

A hardcoat composition comprises (a) an epoxy silane compound, (b) a reactive silicone additive and (c) photo-acid generator. The reactive silicone additive has one of the following general structures:formula (I) or X—SiR¹R²—(O—SiR¹R²)n-X (Formula 2) wherein: R¹, R², and R³ are independently a C1-C6 alkyl group or aromatic group with or without substitution; X is a curable group selected from —OH, —OR, —OC(0)R, —OSiŶY3, —CHzCHrL-SiYVY3, and —C(O)(R)₃, wherein: L is a divalent linkage group; Y¹, Y², and Y³ are independently selected from a C1-C6 alkyl group, and a curable group selected from —OH, —OC(O)R, and —OR, with the proviso that at least one of Y¹, Y², and Y³ is a curable group; R is a C1-C4 alkyl group; and n is at least 2 and m is at least 1, provided that the weight average molecular weight (M_{w}) of the reactive silicone additive is no more than 4200.

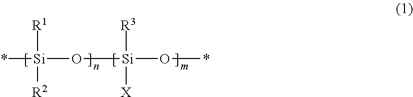

### CROSS-REFERENCE TO RELATED APPLICATIONS

This application claims priority to U.S. Provisional Patent Application Ser. No. 61/549,138, filed on Oct. 19, 2011.

### FIELD

This invention relates to hardcoat compositions that are useful, for example, as a protective layer for a phototool.

### BACKGROUND

In the printed circuit industry, photographic masks or stencils bearing a circuit pattern are known as phototools. Such a stencil, through which a photoresist can be exposed by light (e.g., ultraviolet (UV) light), provides an intricate complex image representing an electrical circuit. The image often consists of many fine lines and junctions spaced closely together. During its use to make printed circuit boards, the phototool is placed face down on a photoresist layer and a contact print is made by exposing the photoresist to light through the phototool. The phototool must then be released from the partially cured photoresist before developing. In this way, a single phototool can be used to make multiple contact prints.

Before, after, or even during processing, a phototool must be carefully inspected through a microscope to ensure that there are no breaks in the fine lines of the image. The continued use of the phototool can cause tiny scratches and abrasions on the phototool surface. The photoresists on which the phototool is placed are usually laminated (for example, by full vacuum) on sheet copper and small burrs or rough edges of the copper sheet can cause scratches as the phototool is transferred from one photoresist to the next. The phototool is also frequently wiped with a cleaning cloth to make sure it is dust and lint free. Small particles of dirt can cause scratching as they are wiped across the phototool surface. Because of this general wear and tear on the phototool surface during normal use, the phototool must be frequently inspected to ensure line continuity. Depending upon the size and the intricacy of the phototool, such microscopic inspections can take 2 to 3 hours.

Due to the fact that phototools are vulnerable to scratching and that abrasion is a serious problem during the normal use of a phototool, protective films and overcoats having release performance are often employed to protect the phototool and allow repeated use of the phototool. For example, polysiloxane films coated with various kinds of pressure sensitive adhesives have been laminated to image-bearing surfaces to protect the image and provide smooth release. Because of their thickness, however, laminating films can cause optical distortion and hence are only used for products with limited resolution. In addition, polysiloxane films are relatively soft and thus provide only limited scratch protection. Thinner and harder protective coatings can be obtained by coating the surfaces of phototools with liquid compositions. Then, the thin liquid coating is hardened to yield the desired protective coat with improved scratch resistance. Epoxy silanes and acrylate esters (for example, polyurethane acrylates) have been used as protective hard coatings because of their resistance to abrasion. Many of these protective overcoats have limited release properties, however, and can therefore stick to the surface of the photoresist even when additional slipping agents are used, particularly when sticky photoresist materials such as high viscosity solder mask inks are present. In addition, many protective coating compositions comprise solvents.

### SUMMARY

In view of the foregoing, we recognize that there is a need in the art for hardcoat compositions that can be used to protect surfaces and objects from scratching and abrasion. We also recognize that for phototool applications, it would be advantageous if protective layers comprising the hardcoat compositions release easily from sticky photoresist materials such as solder mask inks. In addition, we recognize that it would be advantageous if such hardcoat compositions were solventless or essentially solventless.

Briefly, in one aspect, the present invention provides hardcoat compositions comprising (a) an epoxy silane compound, (b) a reactive silicone additive, and (c) photo-acid generator. The reactive silicone additive has one of the following general structures:

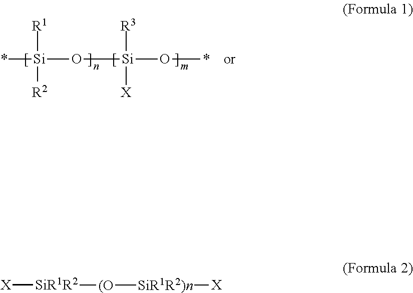

wherein:

R¹, R², and R³ are independently a C1-C6 alkyl group or aromatic group (e.g., phenyl group) with or without substitution;

X is a curable group selected from —OH, —OR, —OC(O)R, —OSiY¹Y²Y³, —CH₂CH₂-L-SiY¹Y²Y³, and —C(OXR)₃, wherein:
L is a divalent linkage group;
Y¹, Y², and Y³ are independently selected from a C1-C6 alkyl group, and a curable group selected from —OH, —OC(O)R, and —OR, with the proviso that at least one of Y¹, Y², and Y³ is a curable group;
R is a C1-C4 alkyl group; and
n is at least 2 and m is at least 1, provided that the weight average molecular weight (M_{w}) of the reactive silicone additive is no more than 4200.

In another aspect, the present invention provides a hardcoat composition comprising (a), (b), (c) (as defined above), and (d) a curable fluorinated additive comprising a curable epoxide group or silane functionality or both.

In yet another aspect, the present invention provides a hardcoat composition comprising (a), (b), (c) (as defined above), and (e) a leveling or wetting agent.

In still another aspect, the present invention provides a cured hardcoat composition comprising the reaction product of components (a), (b), and (c).

As used herein, in the structures * means the site is terminated with an ending group or attached to another chain or cyclized.

As used herein, “epoxy-silane compound” means a compound or materials having at least one polymerizable epoxy group and at least one polymerizable silane group; and “photo-acid generator” means a compound that generates or liberates an acid when exposed to photo-irradiation, and the acid generated is of sufficient strength to initiate cationic chain polymerization of epoxide and reactive silane functional groups.

As used herein, “hydrolyzable group” refers a group capable of being hydrolyzed. Examples include halide, hydroxyl, alkoxy, aryloxy, acyloxy, and polyalkyleneoxy. Preferred hydrolyzable groups include —OR or —OC(O)R, wherein R is a C1-C4 alkyl group. More preferred hydrolyzable groups include —OR wherein R is a C1-C4 alkyl group (e.g., —OCH₃, —OCH₂CH₃, —OCH₂CH₂CH₃, —OCH(CH₃)₂, and

### —OCH₂CH₂CH₂CH₃).

The hardcoat compositions of the invention can provide abrasion-resistance, hardness, clarity, low surface energy with low adhesion and release properties. When a curable fluorinated additive is added, additional properties can be obtained such as, for example, anti-reflection, resistance to staining and soiling, and repellency to stains, soils, solvents, oil, and water.

Advantageously, the compositions of the invention are solventless or essentially solventless, and have a flashpoint of 140° F. or greater. Therefore shipping of the compositions is not governed by the shipping regulations relating to the movement of hazardous materials that cover compositions comprising low boiling point solvents.

As used herein, “solventless or essentially solventless” means that there is no solvent in the composition or that there is a limited amount of solvent, for example, from optional component (d) a curable fluorinated additive comprising a curable epoxide group or silane functionality or both. The solventless or essentially solventless hardcoat compositions of the invention typically comprise less than 10 wt. % (preferably less than 5 wt. %) solvent, based upon the total weight of the hardcoat composition.

Protective layers comprising the cured hardcoat compositions can be used to protect various hard substrates. They are particularly well-suited for protecting phototools from scratching and abrasion. Protective layers comprising the cured hardcoat compositions of the invention have good release properties and therefore do not stick or stick less to photoresist surfaces even when sticky materials such as high viscosity solder masks are present. Phototools with protective layers comprising the cured hardcoat compositions of the invention can advantageously be used to make multiple contact prints.

Protective layers formed from curing the hardcoat compositions of the invention have low surface energy with high receding water contact angles. The protective layer also exhibits good release properties with low peel force. In addition, when fluorochemical additives are included in the compositions they also have high oil contact angles.

The terms “comprises” and variations thereof do not have a limiting meaning where these terms appear in the description and claims.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure.

In this application, terms such as “a,” “an,” and “the” are not intended to refer to only a singular entity, but include the general class of which a specific example may be used for illustration. The terms “a,” “an,” and “the” are used interchangeably with the term “at least one.”

The phrases “at least one of” and “comprises at least one of” followed by a list refers to any one of the items in the list and any combination of two or more items in the list.

As used herein, the term “or” is generally employed in its usual sense including “and/or” unless the content clearly dictates otherwise. The term “and/or” means one or all of the listed elements or a combination of any two or more of the listed elements.

Also herein, all numbers are assumed to be modified by the term “about” and preferably by the term “exactly.” As used herein in connection with a measured quantity, the term “about” refers to that variation in the measured quantity as would be expected by the skilled artisan making the measurement and exercising a level of care commensurate with the objective of the measurement and the precision of the measuring equipment used.

Also herein, the recitations of numerical ranges by endpoints include all numbers subsumed within that range as well as the endpoints (e.g., 1 to 5 includes 1, 1.5, 2, 2.75, 3, 3.80, 4, 5, etc.).

The above summary of the present disclosure is not intended to describe each disclosed embodiment or every implementation of the present disclosure. The description that follows more particularly exemplifies illustrative embodiments. In several places throughout the application, guidance is provided through lists of examples, which examples can be used in various combinations. In each instance, the recited list serves only as a representative group and should not be interpreted as an exclusive list.

### DETAILED DESCRIPTION

### Hardcoat Compositions

The hardcoat compositions of the invention comprise one or more epoxy silane compounds, one or more epoxy-functionalized perfluoropolyether acrylate oligomers, and photo-acid generator.

### Epoxy Silanes

The hardcoat compositions of the invention comprise curable epoxy silane compounds. Curable epoxy silanes are compounds or materials having at least one polymerizable epoxy group and at least one polymerizable silane group, the bridging of these groups being through a non-hydrolyzable aliphatic, aromatic, or aliphatic and aromatic divalent hydrocarbon linkage which may have N, O, and/or S atoms in the linkage chain. The O atoms, for example would be within the chain only as ether or ester linkages. These linkage chains may be generally substituted as is well known in the art, as these substituents on the chain do not greatly affect the functional ability of the epoxy-terminated silanes to undergo the essential reactions necessary to polymerization through the siloxane and epoxy terminal groups. Examples of substituents which may be present on the linkage or bridging moieties are groups such as —NO₂, CH₃(CH₂)ₙCH₂— (wherein n is 1-18), methoxy, ester, amide, urethane, ether, thioether, sulfone, halogen, and the like. In general structural formulas appearing within this description of the invention, such substitution of the bridging moieties is implied unless specifically excluded by language such as “unsubstituted divalent hydrocarbon radical.”

The curable epoxy silane compounds may be monomeric, oligomeric, or polymeric. They may be, for example, acrylates, urethanes, ester-based, or the like.

The curable epoxy silane compounds can be of the general formula:

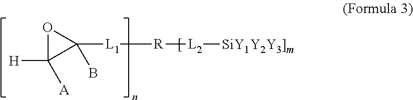

wherein:
L₁ is a divalent linkage;
L₂ is a divalent linkage;
R is multi-valent monomeric, oligomeric, or polymeric residue;
A and B are independently selected from H or C1-C4 alkyl group or connected to each other to form a 5- or 6-membered ring (preferably, an alicyclic or heterocyclic ring);
Y₁, Y₂, and Y₃ are each independently selected from an alkyl group (preferably, a C1-C6 alkyl group), aryl group (preferably, phenyl), or hydrolyzable group, with the proviso that at least one of Y₁, Y₂, and Y₃ is a hydrolyzable group; and
n is at least one and m is at least one (preferably, n is no greater than 6, and m is no greater than 20, and more preferably, n and m are each 1).

Exemplary divalent linkages L₁ and L₂ of Formula 3 include alkylene or alkylene ether, both either linear or branched, or a bond.

Exemplary multi-valent R residues in Formula 3 include oligomeric residues of polyurethane, polyacrylate, and polyester.

In Formula 3, Y₁, Y₂, and Y₃ are each independently selected from a C1-C6 alkyl group, or hydrolyzable group, with the proviso that at least one of Y₁, Y₂, and Y₃ is a hydrolyzable group. Preferably, the hydrolyzable group of Y₁, Y₂, and Y₃ is —OR, wherein R is a C1-C4 alkyl group. Exemplary hydrolyzable group of Y₁, Y₂, and Y₃ includes —OCH₃, —OCH₂CH₃, —OCH₂CH₂CH₃, —OCH(CH₃)₂, and —OCH₂CH₂CH₂CH₃.

Preferably, the curable epoxy silane compounds are epoxy-terminated silane compounds having terminal polymerizable epoxy groups and terminal polymerizable silane groups, the bridging of these groups being as described above.

Other useful epoxy-terminated silane compounds include epoxy-terminated alkoxy silanes of the following structure:

G-L₁-Si(R₂)ₘ—(OR₃)₃₋ₘ (Formula 4)

wherein:
L₁ is a divalent linkage,
R₂ and R₃ independently are C₁-C₄ alkyl groups,
G is a glycidoxy or epoxycyclohexyl group, and
m is 0 or 1.

Exemplary divalent linkages L₁ of Formula 4 include alkylene or alkylene ether, both either linear or branched, or a bond. Preferably, in Formula 4, the divalent linkage L₁ is —CH₂CH₂CH₂O— or —CH₂CH₂—.

Many epoxy-functional alkoxysilanes are suitable, including glycidoxymethyl-trimethoxysilane, glycidoxymethyltriethoxysilane, glycidoxymethyl-tripropoxysilane, glycidoxymethyl-tributoxysilane, β-glycidoxyethyltrimethoxysilane, β-glycidoxyethyltriethoxysilane, β-glycidoxyethyl-tripropoxysilane, β-glycidoxyethyl-tributoxysilane, β-glycidoxyethyltrimethoxysilane, α-glycidoxyethyl-triethoxysilane, α-glycidoxyethyl-tripropoxysilane, α-glycidoxyethyltributoxysilane, γ-glycidoxypropyl-trimethoxysilane, γ-glycidoxypropyl-triethoxysilane, γ-glycidoxypropyl-tripropoxysilane, γ-glycidoxypropyltributoxysilane, β-glycidoxypropyl-trimethoxysilane, β-glycidoxypropyl-triethoxysilane, β-glycidoxypropyl-tripropoxysilane, β-glycidoxypropyltributoxysilane, α-glycidoxypropyl-trimethoxysilane, α-glycidoxypropyl-triethoxysilane, α-glycidoxypropyl-tripropoxysilane, α-glycidoxypropyltributoxysilane, γ-glycidoxybutyl-trimethoxysilane, δ-glycidoxybutyl-triethoxysilane, δ-glycidoxybutyl-tripropoxysilane, δ-glycidoxybutyl-tributoxysilane, δ-glycidoxybutyl-trimethoxysilane, γ-glycidoxybutyl-triethoxysilane, γ-glycidoxybutyl-tripropoxysilane, γ-propoxybutyl-tributoxysilane, δ-glycidoxybutyl-trimethoxysilane, δ-glycidoxybutyl-triethoxysilane, δ-glycidoxybutyl-tripropoxysilane, α-glycidoxybutyl-trimethoxysilane, α-glycidoxybutyl-triethoxysilane, α-glycidoxybutyl-tripropoxysilane, α-glycidoxybutyl-tributoxysilane, (3,4-epoxycyclohexyl)-methyl-trimethoxysilane, (3,4-epoxycyclohexyl)methyl-triethoxysilane, (3,4-epoxycyclohexyl)methyl-tripropoxysilane, (3,4-epoxycyclohexyl)-methyl-tributoxysilane, (3,4-epoxycyclohexyl)ethyl-trimethoxysilane, (3,4-epoxycyclohexyl)ethyl-triethoxysilane, (3,4-epoxycyclohexyl)ethyl-tripropoxysilane, (3,4-epoxycyclohexyl)-ethyl-tributoxysilane, (3,4-epoxycyclohexyl)propyl-trimethoxysilane, (3,4-epoxycyclohexyl)propyl-triethoxysilane, (3,4-epoxycyclohexyl)propyl-tripropoxysilane, (3,4-epoxycyclohexyl)propyl-tributoxysilane, (3,4-epoxycyclohexyl)butyl-trimethoxysilane, (3,4-epoxycyclohexyl)butyl-triethoxysilane, (3,4-epoxycyclohexyl)-butyl-tripropoxysilane, and (3,4-epoxycyclohexyl)butyl-tributoxysilane.

Preferred epoxy-terminated alkoxy silanes are epoxyalkylalkoxysilanes.

Particularly preferred epoxyalkylalkoxysilanes are γ-glicidoxypropyl trimethoxy silane, γ-glycidoxypropylmethyldiethoxysilane and beta-(3,4-epoxycyclohexyl)ethyl-trimethoxysilane.

Examples of more epoxy-terminated silanes useful in the present invention are described, for example, in U.S. Pat. Nos. 4,049,861 and 4,293,606, and include compounds of the general formulae:

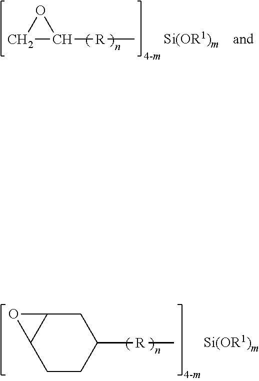

where R=a non-hydrolyzable divalent hydrocarbon radical (aliphatic, aromatic, or aliphatic and aromatic containing) of less than 20 carbon atoms or a divalent radical of less than 20 carbon atoms composed of C, H, N, S, and O atoms (these atoms are the only atoms which may appear in the backbone of the divalent radicals), the last being in the form of ether linkages. No two heteroatoms may be adjacent within the backbone of the divalent hydrocarbon radical. This description defines divalent hydrocarbon radicals for epoxy terminated siloxanes in the practice of this invention. The value of n is from 0 to 1, R¹ is an aliphatic hydrocarbon radical of less than 10 carbon atoms, an acyl radical of less than 10 carbon atoms, or a radical of formula —(CH₂CH₂O)ₖZ in which k is an integer of at least 1 (and preferably, no greater than 10) and Z is an aliphatic hydrocarbon radical of less than 10 carbon atoms or hydrogen, m has values of 1 to 3.

The epoxy silanes used in this invention can be an epoxy silane of the above formula in which R is any divalent hydrocarbon radical such as methylene, ethylene, decalene, phenylene, cyclohexylene, cyclopentylene, methylcyclohexylene, 2-ethylbutylene, and allene or an ether radical such as —CH₂—CH₂—O—CH₂—CH₂—, (CH₂—CH₂O)₂—CH₂—CH₂—,

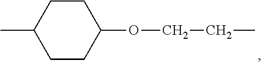

and —CH₂O—(CH₂)₃—, R¹ can be any aliphatic hydrocarbon radical of less than 10 carbon atoms such as methyl, ethyl, isopropyl, butyl, vinyl, alkyl, or any acyl radical of less than 10 carbon atoms such as formyl, acetyl, propionyl, or any radical of the formula —(CH₂CH₂O)ₖZ in which k is an integer of at least 1, for example 2, 5, and 8 (and preferably, no greater than 10) and Z is hydrogen or any aliphatic hydrocarbon radical of less than 10 carbon atoms such as methyl, ethyl, isopropyl, butyl, vinyl, and allyl.

The following compounds are illustrative of some of the epoxy-terminated silanes that are useful in the present invention (wherein ET=ethyl, Pr=propyl, s=saturated, and Me=methyl:

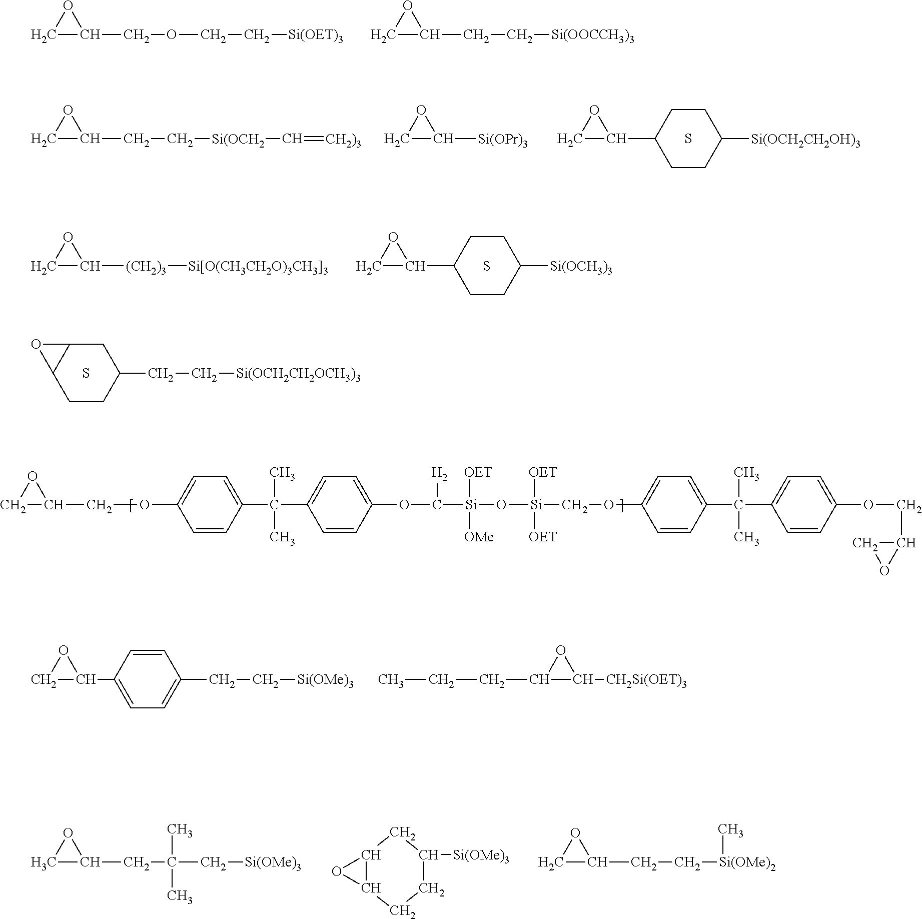

The preparation of most of the above epoxy-terminated silane compounds has been described in U.S. Pat. No. 3,131,161.

Other useful epoxy-terminated silanes are those of the formula:

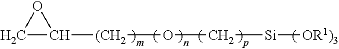

wherein

m is 1 to 6 (preferably 1 to 4),

n is 0 or 1 (preferably 1),

p is 1 to 6 (preferably 1 to 4), and

R¹ is H or alkyl of 1 to 10 carbon atoms (preferably alkyl of 1 to 4 carbon atoms).

In addition to any of the above epoxy silanes, partially hydrolyzed or condensed epoxy silane, which are further curable under photo-irradiation in the presence of photo-acid generator are useful in the present invention, alone or blended with non-hydrolyzed epoxy silanes. These partial hydrolyzates can be formed by the partial hydrolysis of the silane OR¹ groups. Thus the term precondensate includes siloxanes in which some or all of the silicon atoms are bonded through oxygen atoms. Prepolymers are formed by the polymerization of groups other than the silanes as in U.S. Pat. Nos. 4,100,134 and 7,037,585.

Epoxy silanes typically comprise at least 50% by weight of the hardcoat composition. Preferably, they comprise from 75% by weight to 95% by weight of the composition.

### Reactive Silicone Additive

The hardcoat compositions of the invention also comprise a reactive silicone additive. The reactive silicone additive is distinct from an epoxy silane described above. In certain embodiments, the reactive silicone additive does not include epoxy functionality. The epoxy silanes described above and the reactive silicone additive crosslink with themselves and with each other in the presence of acid generated, for example, by cationic photoinitiator, giving the composition durability. In addition, the silicone imparts release properties.

Useful reactive silicone additives are compatible with epoxy silanes and have one of the following general structures:

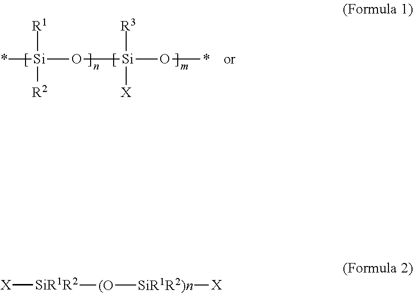

wherein, in Formulas 1 and 2:

R¹, R², and R³ are independently a C1-C6 alkyl group or aromatic group (e.g., phenyl group) with or without substitution;

X is a curable group selected from —OH, —OR, —OC(O)R, —OSiY¹Y²Y³, —CH₂CH₂-L-SiY¹Y²Y³, and —C(O)(R)₃, wherein:
L is a divalent linkage group;
Y¹, Y², and Y³ are independently selected from a C1-C6 alkyl group, and a curable group selected from —OH, —OC(O)R, and —OR, with the proviso that at least one of Y¹, Y², and Y³ is a curable group;
R is a C1-C4 alkyl group; and

n is at least 2 and m is at least 1, provided that the weight average molecular weight (M_{w}) of the reactive silicone additive is no more than 4200.

Exemplary divalent linkages “L” in group “X” of Formula 2 include CH₂ or a bond.

Exemplary substituents on the alkyl and aromatic groups (e., phenyl groups) of R¹, R², and R³ are methyl, ethyl, and propyl, all of which may be optionally fluorinated. For certain embodiments, the alkyl and aromatic groups of R¹, R², and R³ are not substituted.

Preferably, M_{w} of the reactive silicone additive is no more than 4000, more preferably no more than 3000, and most preferably no more than 2000.

In some embodiments, the reactive silicone additive has a viscosity (using glass capillary viscometer) of 90 cSt (centistokes) or less at 25° C.

More preferred reactive silicone additives have one of the following general structures:

HO—Si(CH₃)₂—(O—Si(CH₃)₂)ₙ—OH (Formula 2a)

wherein M_{w} of the reactive silicone additive of Formula 2a is from 400 to 3500.

Z—SiMe₂-(O—SiMe₂)ₙ—OSiMe₂-Z (Formula 2b)

wherein M_{w} of the reactive silicone additive of Formula 2b is from 400 to 3500 (preferably from 500 to 3500, and more preferably from 900 to 1000) and Z is selected from the group consisting of CH₃O—, CH₃CH₂O—, and (C₂H₆O)₃SiCH₂CH₂—.

Silanol-terminated polydiorganosiloxanes of the following formula, which are disclosed in U.S. Pat. No. 3,532,664, are useful as reactive silicone additives in the compositions of the invention:

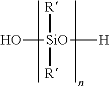

wherein R′ is independently selected from monovalent hydrocarbon radicals (saturated or unsaturated, substituted or unsubstituted, alkyl and/or aryl radicals, preferably, C1-C6 alkyl or RfCH₂CH₂— where Rf is C1-C6 perfluoroalkyl, and more preferably, a C1-C6 unsubstituted alkyl), and n is an integer equal to 1 to 1000 inclusive (for certain embodiments 50 to 1000). These silanol-terminated polydiorganosiloxanes can be made by treating a polydiorganosiloxane such as a polydimethylsiloxane with water in the presence of a suitable acid or base catalyst.

Exemplary polyorganosiloxanes having at least one hydroxyl group bonded to silicon are those disclosed in formula (V) of U.S. Pat. No. 6,018,011.

As disclosed in U.S. Pat. No. 6,204,350, reactive silane functional polysiloxanes can be prepared by a number of convenient methods. For example, equilibration of —SiH functional cyclic siloxanes with cyclic dimethylsiloxanes provides polydimethylsiloxane copolymers with pendant and/or terminal —SiH groups. A disiloxane endblocker is typically included to control the molecular weight. Examples of such endblockers include tetramethyldisiloxane and hexamethyldisiloxane. The platinum-catalyzed hydrosilation reaction of these intermediates with vinyl silanes such as ω-alkenyl silanes provides polysiloxanes having multiple mono-, di-, and tri-alkoxysilane groups. In another approach, polydiorganosiloxanes having either terminal and/or pendant vinyl substitutions are converted into alkoxysilanes by the free-radical addition of mercapto alkyl substituted silanes to the double bonds (see, for example, U.S. Pat. No. 4,269,963).

Typically, the silicon atoms in the polysiloxane polymeric backbone are substituted with methyl groups. When substituents other than methyl groups are desired, a variety of synthesis routes may be used. For example, the linear polymethyl hydrogen siloxane, either with or without copolymerized dimethyl siloxane, can be first hydrosilated with the desired number of vinyl alkoxy or acyloxy silane groups, followed by complete conversion of the remaining SiH groups by reaction with an excess amount of an olefin. In another method, more suitable to the preparation of vinyl substituted polysiloxane intermediates, mixtures of vinyl substituted endblockers, cyclic vinyl methyl siloxanes, cyclic dimethyl siloxanes and other cyclic or polysiloxanes having substituents other than methyl are equilibrated with strong acid catalysts. A convenient source of non-dimethylsiloxanes, in addition to the commercially available cyclic diphenyl siloxanes, is in the form of hydrolysates of various substituted methyldichloro silanes.

When fluorinated derivatives of reactive silane functional materials are used, they are prepared according to methods known in the art. For example, reactive silane functional polysiloxanes can be prepared from the platinum-catalyzed hydrosilation reaction of fluorosilicone starting materials having terminal and/or pendant —SiH functional groups with ω-alkenyl alkoxysilane compounds.

Useful commercially available reactive silicone additives include, for example, silanol terminated polydimethylsiloxanes such as DMS-S12, DMS-S14 and DMS-S15 (all available from Gelest, Inc., Morrisville, Pa.), silanol terminated poly(diphenylsiloxane) such as PDS-9931 (available from Gelest, Inc., Morrisville, Pa.), silanol terminated copolymers of dimethylsiloxane and diphenylsiloxane such as PDS-1615 (available from Gelest, Inc., Morrisville, Pa.), silanol terminated copolymers of dimethylsiloxane and trifluoropropylmethylsiloxane such as FMS-9921 and 9922 (both available from Gelest, Inc., Morrisville, Pa.), methoxy terminated polydimethylsiloxanes such as DMS-XM11 (available from Gelest, Inc., Morrisville, Pa.), dimethoxy(epoxypropoxypropyl) terminated polydimethylsiloxanes such as DMS-EX21(available from Gelest, Inc., Morrisville, Pa.), ethoxy terminated dimethylsiloxanes such as DMS-XE11 (available from Gelest, Inc., Morrisville, Pa.), and triethoxysilylethyl terminated polydimethylsiloxanes such as DMS XT11 (available from Gelest, Inc., Morrisville, Pa.).

The reactive silicone additive is typically present in a composition of the present disclosure in an amount of at least 0.25%, at least 0.5%, or at least 2%, by weight of the composition. The reactive silicone additive is typically present in a composition of the present disclosure in an amount of no greater than 15%, no greater than 10%, or no greater than 5% by weight of the composition.

The reactive silicone additive typically comprises from 0.25% by weight to 15% by weight of the composition (preferably, from 0.5% by weight to 10% by weight of the composition, or more preferably, from 2% by weight to 5% by weight of the composition) for optimized release performance.

### Photoacid Generator

Photoacid generators are cationic photoinitiators. The hardcoat compositions used in the present invention comprise a photoacid generator to cationically polymerize the composition using irradiation, such as ultraviolet (UV) light. Upon UV irradiation, the photoacid generating material liberates an acid that initiates the polymerization (i.e., crosslinking) of the coating composition. In order to facilitate more rapid curing, the liberated acid preferably has a pKa of less than 3; more preferably, less than 1. In some embodiments, the generated acid is superacid (i.e., is an acid with an acidity greater than that of 100% pure sulfuric acid). Useful cationic photoinitiators include diaryliodonium salts, triarylsulfonium salts benzylsulfonium salts, phenacylsulfonium salts, N-benzylpyridinium salts, N-benzylpyrazinium salts, N-benzylammonium salts, phosphonium salts, hydrazinium salts, and ammonium borate salts.

Useful cationic initiators for the purposes of this invention also include the aromatic onium salts, including salts of Group Va elements, such as phosphonium salts, for example, triphenyl phenacylphosphonium hexafluorophosphate, salts of Group VIa elements, such as sulfonium salts, for example, triphenylsulfonium tetrafluoroborate, triphenylsulfonium hexafluorophosphate and triphenylsulfonium hexafluoroantimonate, and salts of Group VIIa elements, such as iodonium salts such as diphenyliodonium chloride and diaryl iodonium hexafluoroantimonate, the latter being preferred. The aromatic onium salts and their use as cationic initiators in the polymerization of epoxy compounds are described in detail in U.S. Pat. No. 4,058,401, “Photocurable Compositions Containing Group VIA Aromatic Onium Salts,” by J. V. Crivello issued Nov. 15, 1977; U.S. Pat. No. 4,069,055, “Photocurable Epoxy Compositions Containing Group VA Onium Salts,” by J. V. Crivello issued Jan. 17, 1978, U.S. Pat. No. 4,101,513, “Catalyst For Condensation Of Hydrolyzable Silanes And Storage Stable Compositions Thereof,” by F. J. Fox et al. issued Jul. 18, 1978; and U.S. Pat. No. 4,161,478, “Photoinitiators,” by J. V. Crivello issued Jul. 17, 1979.

Other cationic initiators can also be used in addition to those referred to above; for example, the phenyldiazonium hexafluorophosphates containing alkoxy or benzyloxy radicals as substituents on the phenyl radical as described in U.S. Pat. No. 4,000,115, “Photopolymerization of Epoxides,” by Sanford S. Jacobs issued Dec. 28, 1976. Preferred cationic initiators for use in the compositions of this invention are the salts of Group VIa elements and especially the sulfonium salts, and also the Group VIIa elements, particularly the diaryl iodonium hexafluororantimonates. Particular cationic catalysts include diphenyl iodonium salts of tetrafluoro borate, hexafluoro phosphate, hexafluoro arsenate, and hexafluoro antimonate; and triphenyl sulfonium salts of tetrafluoroborate, hexafluoro phosphate, hexafluoro arsenate, and hexafluoro antimonate.

U.S. Pat. Nos. 5,286,812 and 6,204,350 also disclose useful acid generating materials.

Examples of cationic photoinitiators are those available under the trade names CYRACURE UVI-6976 (a mixture of triarylsulfonium hexafluoroantimonate salts in propylene carbonate) and UVI-6992 from Dow Chemical, and DAROCUR 1173 from Ciba Geigy Co.

The cationic initiator is typically present in a composition of the disclosure in an amount of at least 1% by weight, based on the total weight of the composition. The cationic initiator is typically present in a composition of the disclosure in an amount of no greater than 1% by weight, based on the total weight of the composition.

Cationic initiator is typically present in the compositions of the invention in a range from 1% to 10% by weight, based on the total weight of the composition.

### Optional Components

In some embodiments, the hardcoat compositions of the invention further comprise compatible fluorinated additives, for example, to provide low surface energy and improved water/oil repellency. The fluorinated additives are preferably curable and comprise a curable epoxide group, silane functionality, or both. The fluorinated additive may be monofunctional or polyfunctional.

Useful fluorinated additives include those having the following general formula:

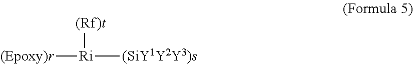

wherein, in Formula 5:
Ri is a multivalent radical of (r+s+t);
Epoxy is selected from

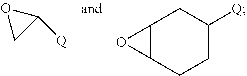

Q is a linkage group between the epoxy and Ri;
Rf is a perfluorinated alkyl group or perfluoropolyether group or a combination thereof;
t is at least 1;
(r+s) is at least 1; and
Y¹, Y², and Y³ are each independently selected from an alkyl group (preferably, a C1-C6 alkyl group), aryl group (preferably, phenyl), or hydrolyzable group, with the proviso that at least one of Y¹, Y², and Y³ is a hydrolyzable group.

In Formula 5, Ri is preferably a residue of a polyisocyanate with a valence of r+s+t.

In Formula 5, preferred Rf groups include, for example, C₄F₉—, C₆F₁₃—, CF₃OCF₂CF₂CF₂—, C₃F₇O(CF₂CF(CF₃)—, C₃F₃)O(CF₂CF(CF₃)O)ₙ—, and the like.

In Formula 5, the Q linkage groups (preferably, C1-C6 alkylene groups) optionally include one or more heteroatoms such as —O—, —S— and —NR³— (wherein R³ is H or a C1-C4 alkyl group), and/or one or more ether, urea, urethane, or ester functionalities.

In Formula 5, t is preferably no greater than 4.

In Formula 5, r is preferably 0-6.

In Formula 5, s is preferably 0-20.

In Formula 5, (r+s) is preferably no greater 30.

In Formula 5, Y¹, Y², and Y³ are each independently selected from a C1-C6 alkyl group, or hydrolyzable group, with the proviso that at least one of Y¹, Y², and Y³ is a hydrolyzable group. Preferably, the hydrolyzable group is —OR, wherein R is a C1-C4 alkyl group. In Formula 5, exemplary hydrolyzable groups Y¹, Y², and Y³ include —OCH₃, —OCH₂CH₃, —OCH₂CH₂CH₃, —OCH(CH₃)₂, and —OCH₂CH₂CH₂CH₃.

Suitable fluorinated additives include, for example, C₄F9CH₂CH₂Si(OMe)₃, C₆F₃CH₂CH₂Si(OMe)₃, C₄F₉CH₂CH₂Si(OEt)₃, C₆F₁₃CH₂CH₂Si(OEt)₃, C₄F₉SO₂NMeCH₂CH₂CH₂Si(OMe)₃, 3-[2-(PERFLUOROHEXYL)ETHOXY]-1,2-EPOXYPROPANE, 1H,1H,2H-PERFLUORO-(1,2-EPOXY)HEXANE, 3-PERFLUOROHEXYL-1,2-EPOXYPROPANE, 1H,1H-HEPTAFLUOROBUTYL EPOXIDE, 4,5,5,6,6,6-HEXAFLUORO-2-(TRIFLUOROMETHYL)BUTYL EPOXIDE, [2,3,3,3-TETRAFLUORO-2-(HEPTAFLUOROPROPOXY)PROPYL]EPOXIDE, [2,3,3,3-TETRAFLUORO-2-(TRIFLUOROMETHOXY)PROPYL]EPOXIDE, 3-PERFLUOROBUTYL-1,2-EPOXYPROPANE, and 1,4-BIS(2′,3′-EPOXYPROPYL)PERFLUORO-1-BUTANE.

Compatible fluorochemical oligomers with curable epoxide groups or silane functionality or both, which are made from acrylate monomers or urethane can also be used.

Useful silane-functionalized perfluoropolyether acrylates disclosed in U.S. Patent Application Pub. No. 2011/0008733, for example, has the following general structures:

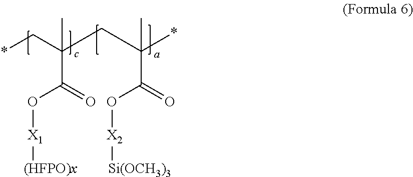

wherein, in Formula 6:
(HFPO) is C₃F₇O(CF(CF₃)CF₂O)ₙCF(CF₃)— wherein n averages from 1 to 50; and preferably n is at least 3 but no great than 50;
X₁ is a divalent linkage (preferably, —CH₂—, —CH₂CH₂—, —C(O)NHCH₂CH₂—, —CH₂OCH₂CH₂—, —CH₂CH₂OCH₂CH₂—, or —C(O)NHCH₂CH₂OCH₂CH₂—);
X₂ is a divalent linkage (preferably —(CH₂)₃—);
x is at least 3 (preferably, at least 5, and preferably no greater than 50);
c is at least 1 (preferably, no greater than 50); and
a is at least 1 (preferably, no greater than 500);
   or

(R_{f}QXC(O)NH)ₘ—Rᵢ-(NHC(O)XQ(Si(Y)ₚ)(R₂)₃₋ₚ)_{q})ₙ (Formula 7)

wherein, in Formula 7:
R_{f} is a monovalent perfluoropolyether moiety composed of groups having the formula F(R_{fc}O)_{w}C_{d}F_{2d}— wherein each R_{fc} is a fluorinated C1-C6 alkylene, w is at least 2 (and preferably, no greater than 50), and d is 1-6;
Q is independently a connecting group of valence at least 2, and may contain heteroatoms, such as —O—, —S— and —NR₃—;
X is O, S, or NR, wherein R is H or lower alkyl of 1 to 4 carbon atoms;
Ri is a residue of a multi-isocyanate;
Y is a hydrolyzable group (preferably, selected from —OR₂ and —OC(O)R₂);
R₂ is a lower alkyl of 1 to 4 carbon atoms;
R₃ is H, —R₄-(Si(Y)ₚ(R₂)₃₋ₚ)_{q})ₙ or R₂;
R₄ is a C1-C6 alkylene or C1-C6 alkylene ether,
m is at least 1;
n is at least 1;
p is 1, 2, or 3;
q is from 1 to 6; and

m+n is from 2 to 10;

or

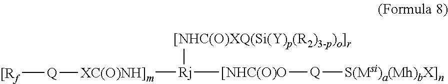

wherein, in Formula 8:
R_{f} is a monovalent perfluoropolyether moiety (preferably as defined above in Formula 7);
Q is as defined above in Formula 7;
Rⱼ is aresidue of a multi-isocyanate;
X is the residue of an initiator or hydrogen;
M^{si} is a radical from an acrylate monomer with a curable silane group of the formula —SiY¹Y²Y³, wherein Y¹, Y², and Y³ are independently halogen, alkyl??, or hydrolyzable alkoxy groups, with the proviso that —SiY¹Y²Y³ includes no more than two alkyl groups;
M^{h} is the radical from one or more hydrocarbon acrylate monomers;
m is at least 1 (and preferably no greater than 3);
b is zero to 20 (preferably, 0-10);
n is at least 1 (preferably, 1-3);
p is 1, 2, or 3 (preferably, 1 or 2);
r+n is at least 1;
a is at least 1 when r is 0;
o is 1 to 4; and
r is zero to 4.

In Formula 8, X is H or the residue of a radical initiator for the oligomerization of an acrylate-silane monomer as described in U.S. Patent Application Serial No. 2011/0008733.

A useful epoxy-functionalized perfluoropolyether acrylate oligomer disclosed in U.S. Patent Application Pub. No. 2011/0027702 has the general formula:

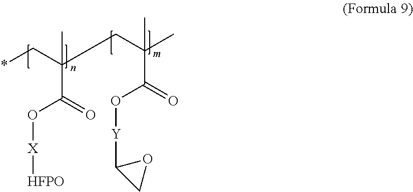

wherein, in Formula 9:
HFPO is perfluoropolyether made from the oligomerization of hexafluoropropene oxide having an average molecular weight of 1,000 or higher,
X and Y are independently divalent linkage groups;
n is at least 1 (preferably, no greater than 50); and
m is at least 1 (preferably, no greater than 500).

In Formula 9, X is preferably a divalent linkage group selected from —CH₂—, —CH₂CH₂—, —C(O)NHCH₂CH₂—, —CH₂OCH₂CH₂—, —CHCH₂OCH₂CH₂—, and —C(O)NHCH₂CH₂OCH₂CH₂—.

In Formula 9, Y is preferably —(CH₂)ₚ— wherein p is 1 to 6, and —(CH₂)_{q}—O—(CH₂)ᵣ— wherein q and r are independently zero to 6, which may be linear or branched, and further wherein one and only one of q and r may be zero.

In addition, also disclosed in U.S. Patent Application Pub. No. 2011/0027702 is a fluorinated acrylate co-oligomer comprising both epoxide and silane functionalities:

(M^{F})a(M^{E})b(M^{S})c (Formula 10)

wherein, in Formula 10:
M^{F} derived from a fluorinated (meth)acrylate;
M^{E} derived from an epoxy (meth)acrylate;
M^{S} derived from a silane (meth)acrylate; and
in certain embodiments, a, b, and c are at least 1 (preferably, a, b, and c are no greater than 100), and in certain embodiments, a is 1-100, b is 0-100, c is 0-100.

If desired, a fluorinated additive can be used in a composition of the present disclosure in an amount of at least 0.1 wt. %, based on the total weight of the hardcoat formulation. If desired, a fluorinated additive can be used in a composition of the present disclosure in an amount of no greater than 5 wt. %, based on the total weight of the hardcoat formulation.

If desired, generally from 0.1 wt. % to 5 wt. % of the fluorinated additive can be used in the hardcoat formulation.

In some embodiments, the hardcoat compositions of the invention further comprise a compatibilizer, leveling agent, wetting agent, or a combination thereof. Compatibilizers may be selected from modified silicones with a group or segment having high compatibility or solubility with epoxy silane compounds, which modify the interfaces of the epoxy silane compound and the reactive silicone additive to facilitate formation of stable and uniform blends and to help form smooth and uniform coatings. Solvent-free compatibilizers are preferred for the coating. Useful compatibilizers include, for example, solventless BYK-308, 307, and 333 available from BYK Additives and Instruments. Leveling agents and wetting agents are useful for optimizing flow and leveling and providing a smooth uniform coating.

The hardcoat compositions can further include one or more polyepoxide compounds such as diepoxides. Diepoxide compounds can, for example, accelerate polymerization of the composition. They can also be used to adjust the softness or to reduce brittleness of the cured composition.

Representative suitable diepoxide comonomers include those disclosed in U.S. Pat. No. 4,293,606 (Zollinger et al.) of the formula:

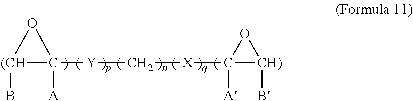

wherein n=1 to 6, X and Y independently represent (1) —OCH₂)ₘ—, wherein m=1 or 2 and the terminal carbon atom of this group is directly connected to the carbon of the epoxy group, or (2)

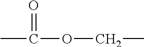

with the bond from the carbonyl carbon atom directly connected to the bridging group CH₂n, p+q=1 or 2 and p and q are independently 0 or 1, A and B, and A′ and B′ are independently H or, when fused together as A and B or A′ and B′, the atoms necessary to form a 5- or 6-membered cycloaliphatic ring.

Preferably, the diepoxide comonomer is a cycloaliphatic diepoxide compound. A preferred diepoxide compound is 3,4-epoxycyclohexylmethyl-3,4-epoxycyclohexanecarboxylate.

Representative useful epoxy resins are D.E.R. 317, 324, 325, 330, 331, 332, 337, 362, 364, 38, 732 and 736 from Dow Chemical Company; GE-20, 21, 22, 23, 24, 25, 29, 30, 31, 35, 36 and 38 from CVC Thermoset Specialties; EPON 235, 813, 824, 825, 826, 827, 828, 829, 830, 834, 862, 863 872, and 8280 from HEXION Special Chemicals.

If used, diepoxide comonomers are typically present in the compositions of the invention in amounts of less than 40% by weight, based on the total weight of the composition.

The hardcoat compositions of the invention may also comprise other optional components such as, for example, curable mono- and/or di-silanes (for example, to adjust hardness), surfactant, matting agents, inorganic particles, and the like.

In another aspect, the protective coating compositions may also comprise a crosslinkable compound (for example, for coating hardness adjustment) represented by formula:

(R)_{q}M(R¹)_{p-q} (Formula 12)

wherein, in Formula 12:
R is selected from the group consisting of alkyl, aryl, arylalkylenyl, and alkylarylenyl;
M is selected from the group consisting of Si, Ti, Zr, and Al (preferably, M is Si);
R¹ is hydrolyzable group (preferably selected from the group consisting of halide, hydroxyl, alkoxy, aryloxy, acyloxy, and polyalkyleneoxy);
p is 3 or 4; and
q is 0, 1, or 2.

In Formula 12, R is preferably methyl, ethyl, or isopropyl.

In Formula 12, R¹ is preferably —OCH₃, —OCH₂CH₃, —O-i-Pr, —O-n-Bu, —OC₂H₄OCH₃, —OC₂H₄OC₂H₄OCH₃.

Representative compounds of this formula include tetramethoxysilane, tetraethoxysilane, methyltriethoxysilane, dimethyldiethoxysilane, octadecyltriethoxysilane, methyltrichlorosilane, tetramethyl orthotitanate, tetraethyl orthotitanate, tetraisopropyl orthotitanate, tetraethylzirconate, tetraisopropylzirconate, and tetrapropylzirconate.

If used, the crosslinkable silanes are typically present in the compositions of the invention in amounts of less than 40% by weight, based on the total weight of composition.

In some embodiments, the hardcoat composition can comprise a cross-linkable nano-compound, for example, for adjusting coating hardness. Examples of cross-linkable nano-compounds include nano-silica, nano-silsesquioxane, and the like.

### Methods and Articles

The hardcoat compositions of the invention can be used to provide durability, clarity, stain- and soil-resistance, water- and soil-repellency, easy-cleaning, and/or release properties to a hard substrate such as, for example, a substrate comprising natural stone, man-made stone, plastics, ceramic, vinyl, wood, masonry, cork, glass, or the like. The hardcoat composition can be applied using coating techniques known in the art, and then cured (that is, cationically polymerized) using ultraviolet light. Typically, when the protective coating is used on a hard substrate, the protective layer will be from 0.1 mil to 2 mils thick, but suitable thicknesses will depend upon the application.

The hardcoat compositions described above are particularly useful for forming a protective layer on phototools to provide scratch- and abrasion-resistance, as well as release properties. Phototools are typically made using a computer-aided design (CAD) system to prepare data for an exposure apparatus (for example, a photo-plotter) based on a target blueprint or data. Then, this data is used to perform direct writing of a designed pattern (for example, a circuit pattern) onto an emulsion photographic dry plate, which has been prepared by forming a film surface of a photosensitive emulsion layer on an optically clear substrate (for example, a glass substrate, fused silica or polyethylene terephthalate (PET), polycarbonate, or poly(methyl)methacrylate substrate). Optically clear substrates typically have low haze (for example, less than 5% or even less than 2%) and are substantially transparent (that is, they typically allow the passage of 95% or more (preferably 98% or more) of visible and ultraviolet light). The photographic dry plate with the pattern thereon is then developed, fixed, washed in water, and dried. It may then be examined for defects and, if necessary, retouched.

The photosensitive emulsion layer typically comprises a silver halide emulsion or a diazo emulsion. Thus, the film surface is relatively soft and easily scratched or marked. Chrome metal absorbing film may also be used.

The hardcoat compositions of the invention can be coated on the substrate of the phototool by any useful coating technique known in the art. The hardcoat composition can then be cured on the phototool using UV light to form the protective layer. Typically, the protective layer comprising the cured hardcoat composition will be from 0.5 microns to 40 microns thick; preferably, from 2 microns to 15 microns thick; more preferably, from 2 microns to 10 microns thick.

### Exemplary Embodiments

1. A hardcoat composition comprising:
(a) an epoxy silane compound,
(b) a reactive silicone additive having one of the following general structures:

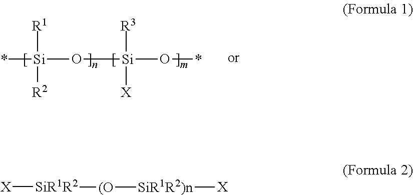

wherein:
R¹, R², and R³ are independently a C1-C6 alkyl group or aromatic group with or without substitution;
X is a curable group selected from —OH, —OR, —OC(O)R, —OSiY¹Y²Y³, —CH₂CH₂-L-SiY¹Y²Y³, and —C(OXR)₃, wherein:
   L is a divalent linkage group;
   Y¹, Y², and Y³ are independently selected from a C1-C6 alkyl group, and a curable group selected from —OH, —OC(O)R, and —OR, with the proviso that at least one of Y¹, Y², and Y³ is a curable group;
   R is a C1-C4 alkyl group; and
n is at least 2 and m is at least 1, provided that the weight average molecular weight (M_{w}) of the reactive silicone additive is no more than 4200; and
(c) photo-acid generator.

2. The hardcoat composition of embodiment 1 comprising 15 wt. % or less of the reactive silicone additive based upon the total weight of the hardcoat composition.

3. The hardcoat composition of embodiment 2 comprising from 2 wt. % to 5 wt. % of the reactive silicone additive based upon the total weight of the hardcoat composition.

4. The hardcoat composition of any of embodiments 1-3 wherein the reactive silicone additive has a viscosity of 90 cSt or less at 25° C.

5. The hardcoat composition of any of embodiments 1-4 wherein the reactive silicone additive has the following general structure:

HO—Si(CH₃)₂—(O—Si(CH₃)₂)ₙ—OH (Formula 2a)

wherein M_{w} of the reactive silicone additive of Formula 2a is from 400 to 3500.

6. The hardcoat composition of any of embodiments 1-4 wherein the reactive silicone additive has the following general structure:

Z—SiMe₂-(O—SiMe₂)ₙ—OSiMe₂-Z (Formula 2b)

wherein M_{w} of the reactive silicone additive of Formula 2b is from 400 to 3500 and Z is selected from the group consisting of CH₃O—, CH₃CH₂O—, and (C₂H₆O)₃SiCH₂CH₂—.

7. The hardcoat composition of any of embodiments 1-6 wherein the epoxy silane compound is an epoxy-terminated silane compound.

8. The hardcoat composition of embodiment 7 wherein the epoxy silane compound is selected from the group consisting of γ-glicidoxypropyl trimethoxy silane, γ-glycidoxypropylmethyldiethoxysilane, and beta-(3,4-epoxycyclohexyl)ethyl-trimethoxysilane.

9. The hardcoat composition of any of embodiments 1-8 further comprising a compatibilizer, a leveling agent, a wetting agent, or a combination thereof.

10. The hardcoat composition of claim any of embodiments 1-9 further comprising (d) a curable fluorinated additive comprising a curable epoxide group or silane functionality or both.

11. The hardcoat composition of embodiment 10 wherein the curable fluorinated additive has the following general structure:

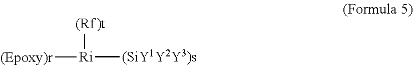

wherein, in Formula 5:
Ri is a multivalent radical of (r+s+t);
Epoxy is selected from

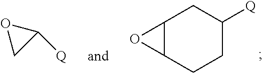

Q is a linkage group between the epoxy and Ri;
Rf is a perfluorinated alkyl group or perfluoropolyether group or a combination thereof;
t is at least 1;
(r+s) is at least 1; and
Y¹, Y², and Y³ are each independently selected from an alkyl group, aryl group, or hydrolyzable group, with the proviso that at least one of Y¹, Y², and Y³ is a hydrolyzable group.

12. The hardcoat composition of any of embodiments 1-11 wherein the composition is solventless or essentially solventless.

13. The hardcoat composition of any of embodiments 1-12 wherein the composition has a flash point of 140° F. or greater.

14. A hardcoat composition comprising the reaction product of:

(a) an epoxy silane compound,

(b) a reactive silicone additive having one of the following general structures:

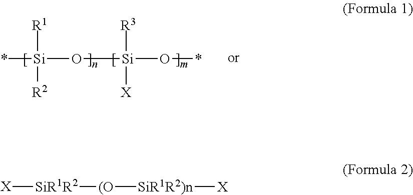

wherein:
R¹, R², and R³ are independently a C1-C6 alkyl group or aromatic group with or without substitution;
X is a curable group selected from —OH, —OR, —OC(O)R, —OSiY¹Y²Y³, —CH₂CH₂-L-SiY¹Y²Y³, and —C(OXR)₃, wherein:
   L is a divalent linkage group;
   Y¹, Y², and Y³ are independently selected from a C1-C6 alkyl group, and a curable group selected from —OH, —OC(O)R, and —OR, with the proviso that at least one of Y¹, Y², and Y³ is a curable group;
   R is a C1-C4 alkyl group; and
n is at least 2 and m is at least 1, provided that the weight average molecular weight (M_{w}) of the reactive silicone additive is no more than 4200; and

(c) photo-acid generator.

15. The hardcoat composition of embodiment 14 comprising the reaction product of (a), (b), (c) and (d) a curable fluorinated additive comprising a curable epoxide group or silane functionality or both.

16. The hardcoat composition of embodiment 15 wherein the curable fluorinated additive has the following general structure:

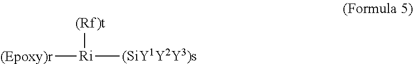

wherein, in Formula 5:
Ri is a multivalent radical of (r+s+t);
Epoxy is selected from and

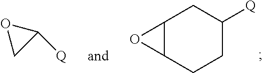

Q is a linkage group between the epoxy and Ri;
Rf is a perfluorinated alkyl group or perfluoropolyether group or a combination thereof;
t is at least 1;
(r+s) is at least 1; and
Y¹, Y², and Y³ are each independently selected from an alkyl group, aryl group, or hydrolyzable group, with the proviso that at least one of Y¹, Y², and Y³ is a hydrolyzable group.

17. The hardcoat composition of any of embodiments 15-16 wherein the composition is solventless or essentially solventless.

18. The hardcoat composition of any of embodiments 15-17 wherein the composition has a flashpoint of 140° F. or greater.

19. A coated article comprising a substrate and a protective layer comprising the cured hardcoat composition of any of embodiments 1-18 on at least a portion of the substrate.

20. A phototool comprising an optically clear substrate having a designed pattern, and a protective layer comprising the cured hardcoat composition of any of embodiments 1-18 on the substrate.

### EXAMPLES

Objects and advantages of this invention are further illustrated by the following examples, but the particular materials and amounts thereof recited in these examples, as well as other conditions and details, should not be construed to unduly limit this invention.

### Materials

Materials utilized for the examples are shown in Table 1.

TABLE 1
Materials List

| Compound | Source | Description |
|---|---|---|
| A-186 | GE Advanced Materials, Bergen op Zoom | Beta-(3,4-epoxycyclohexyl)ethyltrimethoxysilane) |
| | Netherlands | |
| A-187 | GE Advanced Materials Bergen op Zoom, | Gamma-Glycidoxypropyltrimethoxysilane |
| | Netherlands | |
| FX-1000 | 3M Co., St. Paul, MN | Epoxy-silane based SCOTCHGARD phototool protector |
| UVI-6976 | Union Carbide Company, Houston, TX | Triarylsulphonium hexafluoroantimonate, |
| | | 50% in propylene carbonate |
| DMS-S12 | Bergen op Zoom, Netherlands | Silanol Terminated Polydimethylsiloxane |
| DMS-S14 | Gelest, Morrisville, PA | Silanol Terminated Polydimethylsiloxane |
| DMS-S15 | Gelest, Morrisville, PA | Silanol Terminated Polydimethylsiloxane |
| DMS-S21 | Gelest, Morrisville, PA | Silanol Terminated Polydimethylsiloxane |
| DMS-XM11 | Gelest, Morrisville, PA | Alkoxy terminated polydimethylsiloxane |
| DMS-XE11 | Gelest, Morrisville, PA | Alkoxy terminated polydimethylsiloxane |
| DMS-XT11 | Gelest, Morrisville, PA | Alkoxy terminated polydimethylsiloxane |
| DER732 | Dow Chemical Co., Midland, MI | Epoxy resin |
| CoatOsil 77 | Momentive Performance Materials, Albany, NY | Poly(ethylene oxide) pendent trisiloxane |
| CoatOsil 2810 | Momentive Performance Materials, Albany, NY | Epoxy terminated polysiloxane |
| CoatOsil 3500 | Momentive Performance Materials, Albany, NY | Silicone polyether block linear copolymer |
| CoatOsil 7510 | Momentive Performance Materials, Albany, NY | Polyether pendent silicone block copolymer |
| CoatOsil 7600 | Momentive Performance Materials, Albany, NY | Polyether pendent silicone block copolymer |
| CoatOsil 7650 | Momentive Performance Materials, Albany, NY | Polyether pendent silicone block copolymer |
| CoatOsil 7608 | Momentive Performance Materials, Albany, NY | Poly(ethylene oxide) pendent trisiloxane |
| BYK-333 | BYK Additives and Instruments, Wesel, Germany | Silicone polyether surface additive |
| PFE-Silane | 3M Co., St. Paul MN, | Perfluoropolyether based silane, FA-3 in |
| | | U.S. Patent Application Pub. No. 2011/0008733 |
| FC-4405 | 3M Co., St. Paul, MN | C₄F₉SO₂NMe(CH₂)₃Si(OMe)₃, |
| | | FA-1 in WO 2011/011167 |
| FX-2000 | 3M Co., St. Paul MN, | Epoxy-silane based SCOTCHGARD phototool |
| | | protector with fluorochemical additive |
| FF-400 | Dow Corning Co., Midland, MI | Polyether pendent silicone block copolymer |
| FF-1248 | Dow Corning Co., Midland, MI | Silicone fluid |
| Q2-5211 | Dow Corning Co., Midland, MI | Poly(ethylene oxide) pendent trisiloxane |
| Q2-5212 | Dow Corning Co., Midland, MI | Poly(ethylene oxide) pendent trisiloxane |
| MCR-E11 | Gelest, Morrisville, PA | Mono-(2,3epoxy)propylether terminated |
| | | polydimethylsiloxane |
| ECMS-924 | Gelest, Morrisville, PA | Epoxycyclohexylethylmethylsiloxane and |
| | | dimethylsiloxane copolymer |
| DMS-E09 | Gelest, Morrisville, PA | Epoxypropoxypropyl terminated |
| | | polydimethylsiloxane |

### Test Methods

### Release

An Imass SP2000 peel tester (IMASS Inc., Accord, Mass.) was used for all release tests. Tests were performed at 21° C. at 50% RH. A 2.54 cm wide piece of 3M 610 cellophane tape was laminated to the sample coatings with two passes of a 2 kg rubber roller, then peeled at an angle of 180° and a speed of 2.3 meters per minute for 5 seconds. Typically, 3 measurements were made at different positions and the mean reported.

### Re-adhesion

The tape strips peeled in the Release test were laminated to the surface of a clean stainless steel panel with two passes of a 2 kg rubber roller. An Imass SP2000 was used to peel the tape at an angle of 180° and a speed of 30 cm per minute for 10 seconds. Typically, 3 measurements were made at different positions and the mean reported. The Imass SP2000 peel tester was used to record the peel force.

### Appearance

A visual assessment of the coating mixture and the cured coating was made. The coating mixture was reported as homogeneous, hazy, or phase separated. The cured coating was reported as homogeneous (complete coverage, not dewetted) or dewetted.

### Contact Angle

Advancing, receding, and static contact angles were measured with a Krus DSA100 (Cruss GmbH, Hamburg, Germany). Measurements were made using reagent-grade hexadecane from Aldrich Chemical Co., and deionized water filtered through a filtration system from Millipore Corp. of Billerica, Mass. on a video contact angle system analyzer (VCA-2500XE) from AST Products of Billerica, Mass. Reported values are the average of at least three drops measured on the right and the left sides of the drops. Drop volumes were 5 microliters for static contact angle measurements and 1-3 microliters for advancing and receding contact angle measurements.

### EXAMPLES

### E-2

In a glass bottle, 0.2 g DMS-S12 was combined with 0.3 g BYK-333 and 9.5 g A187. This coating mixture was sealed under nitrogen and mixed by shaking for 2 minutes. Nearly no bubbles were observed.

A coating formulation was then prepared by mixing 9.2 g of the coating mixture and 0.8 g UVI-6976. This formulation was then coated on primed polyester with a No. 6 wire rod, and cured in air with a 600 watt H-bulb (Fusion UV Systems, Gaithersburg, Md.) on a web moving at a speed of 6 meters per minute. The cured coating was then ready for evaluation.

### Other Examples (E) and Comparatives (C)

Other formulations were prepared as E-2 with the compositions described in the tables.

### Adhesive Tape

Cellophane tape (SCOTCH Premium Cellophane Tape 610, 2.54 cm width, 3M Company, St. Paul, Minn.) was used for release, adhesion test as a “Control” (adhesion to stainless steel panel without laminating to release coating).

### Results

Test results for example formulations (E) containing silanol terminated silicones and comparative formulations (C) are summarized in Table 2. A laminating silicone film, available from Sekisui Chemical, Japan, was laminated to a PET film and utilized as a comparative (“C-3”).

The effect of silanol-terminated silicone concentration on release performance is shown in Table 3. In some formulations, additional additive was included to improve the coating quality and other performance features.

TABLE 2
Epoxysilane With Silanol Terminated Silicone

| | | | | | | | Re- |
|---|---|---|---|---|---|---|---|
| | Formulation | | | Appearance | | Release | adhesion |
| Sample | Epoxysilane | Silicone | Additive | Mixture | Coating | (g/2.54 cm) | |
| Control | | | | — | — | — | 620 |
| C-1 | A187, | 0 | 0 | H[a] | H | 1464 | 736 |
| | 100% | | | | | | |
| E-1 | A187, | DMS-S12, | 0 | H | D[b] | —[c] | — |
| | 98% | 2% | | | | | |
| E-2 | A187, | DMS-S12, | BYK-333, | H | H | 17 | 442 |
| | 95% | 2% | 3% | | | | |
| E-3 | A187, | DMS-S14, | 0 | H | H | 11 | 345 |
| | 98% | 2% | | | | | |
| E-4 | A187, | DMS-S15, | 0 | H | H | 14 | 446 |
| | 98% | 2% | | | | | |
| E-5 | A187, | DMS-S21, | 0 | PS[d] | — | — | — |
| | 98% | 2% | | | | | |
| C-2 | FX-1000, | 0 | 0 | H | H | 327 | 662 |
| | 100% | | | | | | |
| E-6 | FX-1000, | DMS-S14, | 0 | H | H | 50 | 630 |
| | 98% | 2% | | | | | |
| E-7 | FX-1000, | DMS-S15, | 0 | H | H | 142 | 564 |
| | 98% | 2% | | | | | |
| E-8 | FX-1000, | DMS-S12, | 0 | H | H | 28 | 426 |
| | 98% | 2% | | | | | |
| E-9 | FX-1000, | DMS-S21, | 0 | PS | — | — | — |
| | 98% | 2% | | | | | |
| E-10 | FX-1000, | DMS-S12, | DER 732, | H | H | 24 | 433 |
| | 93% | 2% | 5% | | | | |
| E-11 | FX-1000, | DMS-S12, | DER 732, | H | H | 35 | 523 |
| | 88% | 2% | 10% | | | | |
| C-3 | Silicone film | 0 | 0 | — | — | 32 | 676 |
| C-4 | A186, | 0 | 0 | H | H | 1260 | 407 |
| | 100% | | | | | | |
| E-12 | A186. | DMS-S14, | 0 | H | H | 288 | 500 |
| | 98% | 2% | | | | | |
| E-13 | A186. | DMS-S14, | PFE-Silane, | H | H | 197 | 450 |
| | 96% | 2% | 2% | | | | |

[a]Homogeneous
[b]Dewetted
[c]Not tested/Not measured
[d]Phase Separated

TABLE 3
Effect of Silicone Concentration on Release

| | Formulation | | Release | Re-adhesion |
|---|---|---|---|---|
| Sample | Epoxysilane | Silicone | (g/2.54 cm) | |
| E-14 | FX-1000, 99% | DMS-S12, 1% | 19 | 354 |
| E-15 | FX-1000, 95% | DMS-S12, 5% | 7 | 238 |
| E-16 | FX-1000, 90% | DMS-S12, | 3 | 133 |
| | | 10% | | |
| E-17 | FX-1000, 80% | DMS-S12, | 2 | 56 |
| | | 20% | | |

The release durability of an example coating is shown in Table 4. The release of 10 separate pieces of cellophane tape from the same spot on the sample coating was measured.

TABLE 4
Coating Durability

| | Formulation | | Release | Re-adhesion |
|---|---|---|---|---|
| Sample | Epoxysilane | Silicone | (g/2.54 cm) | |
| Control | | | —[a] | 524 |
| E-6 | FX-1000, 98% | DMS-S14, 2% | 17 | 354 |
| | | | 17 | 404 |
| | | | 18 | 446 |
| | | | 19 | 438 |
| | | | 20 | 470 |
| | | | 21 | 510 |
| | | | 21 | 502 |
| | | | 22 | 527 |
| | | | 20 | 518 |
| | | | 24 | 527 |

[a]Not tested

Release values for formulations containing alkoxy-terminated silicones are shown in Table 5.

TABLE 5
Epoxysilane With Alkoxy Terminated Silicone

| | | | | | Re- | Re- |
|---|---|---|---|---|---|---|
| Sam- | Formulation | | Appearance | | lease | adhesion |
| ple | Epoxysilane | Silicone | Mixture | Coating | (g/2.54 cm) | |
| C-2 | FX-1000, | 0 | —[a] | — | 359 | 475 |
| | 100% | | | | | |
| E-18 | FX-1000, | DMS-XE11, | H[b] | H | 208 | 506 |
| | 99% | 1% | | | | |
| E-19 | FX-1000, | DMS-XE11, | H | H | 3 | 246 |
| | 98% | 2% | | | | |
| E-20 | FX-1000, | DMS-XE11, | H | H | 2 | 195 |
| | 95% | 5% | | | | |
| E-21 | FX-1000, | DMS-XM11, | Z[c] | H | 4 | 307 |
| | 98% | 2% | | | | |
| E-22 | FX-1000, | DMS-XT11, | H | H | 34 | 497 |
| | 99% | 1% | | | | |
| E-23 | FX-1000, | DMS-XT11, | H | H | 8 | 342 |
| | 98% | 2% | | | | |

[a]Not tested
[b]Homogeneous
[c]Hazy

Contact angles were measured for several representative samples. The addition of a fluorinated compound was found to increase the hexadecane contact angle. The data are presented in Table 6.

TABLE 6
Contact Angles

| | | | | Contact Angles | | | |
|---|---|---|---|---|---|---|---|
| | Formulation | | | Water | Hexadecane | | |
| Sample | Epoxysilane | Silicone | Additive | Static | Advancing | Receding | Static |
| C-2 | FX-1000, | 0 | 0 | 99 | 35 | 34 | 35 |
| | 100% | | | | | | |
| E-19 | FX-1000, | DMS-XE11, | 0 | 87 | —[a] | — | 26 |
| | 98% | 2% | | | | | |
| E-24 | FX-2000, | DMS-XE11, | 0 | 109 | 72 | 61 | 68 |
| | 98% | 2% | | | | | |
| C-4 | A- 186, | 0 | 0 | 77 | 26 | 24 | 23 |
| | 100% | | | | | | |
| E-25 | A- 186, | DMS-XE11, | 0 | 98 | 37 | 30 | 31 |
| | 98% | 2% | | | | | |
| E-26 | A- 186, | DMS-XE11, | FC-4405, | 92 | 45 | 36 | 43 |
| | 93% | 2% | 5% | | | | |
| E-27 | A- 186, | DMS-XE11, | PFE-Silane, | 108 | 71 | 65 | 68 |
| | 90% | 2% | 8% | | | | |

[a]Not tested

Comparative formulations are shown in Table 7. The silicones utilized in these formulations are not di-hydroxy or di-alkoxy terminated. All cured coatings with these silicones showed limited (>100 g/2.54 cm) release.

TABLE 7
Comparative Samples

| | | | | Re- |
|---|---|---|---|---|
| | Formulation | | Release | adhesion |
| Sample | Epoxysilane | Silicone | (g/2.54 cm) | |
| C-2 | FX-1000, | 0 | 325 | 406 |
| | 100% | | | |
| C-5 | FX-1000, 98% | CoatOsil 77, 2% | 293 | 477 |
| C-6 | FX-1000, 98% | CoatOsil 3500, 2% | 199 | 455 |
| C-7 | FX-1000, 98% | CoatOsil 7510, 2% | 231 | 483 |
| C-8 | FX-1000, 98% | CoatOsil 7650, 2% | 205 | 504 |
| C-9 | FX-1000, 98% | CoatOsil 7600, 2% | 142 | 485 |
| C-10 | FX-1000, 98% | CoatOsil 7608, 2% | 157 | 513 |
| C-11 | FX-1000, 98% | CoatOsil 2810, 2% | 267 | 411 |
| C-12 | FX-1000, 95% | CoatOsil 2810, 5% | 246 | 408 |
| C-13 | FX-1000, 98% | Q2-5211, 2% | 300 | 434 |
| C-14 | FX-1000, 98% | Q2-5212, 2% | 165 | 440 |
| C-15 | FX-1000, 98% | FF-400, 2% | 298 | 413 |
| C-16 | FX-1000, 98% | FF-1248, 2% | 155 | 435 |
| C-17 | FX-1000, 98% | MCR-E11, 2% | 365 | 414 |
| C-18 | FX-1000, 98% | ECMS-924, 2% | 140 | 512 |
| C-19 | FX-1000, 98% | DMS-E09, 2% | 182 | 558 |

The complete disclosures of the publications cited herein are incorporated by reference in their entirety as if each were individually incorporated. Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

1. A hardcoat composition comprising:
(a) an epoxy silane compound,
(b) a reactive silicone additive having one of the following general structures: 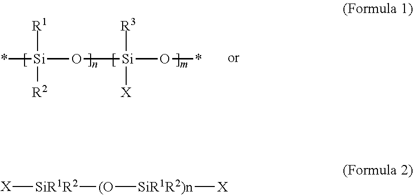
wherein:
R¹, R², and R³ are independently a C1-C6 alkyl group or aromatic group with or without substitution;
X is a curable group selected from —OH, —OR, —OC(O)R, —OSiY¹Y²Y³, —CH₂CH₂-L-SiY¹Y²Y³, and —C(OXR)₃, wherein:
L is a divalent linkage group;
Y¹, Y², and Y³ are independently selected from a C1-C6 alkyl group, and a curable group selected from —OH, —OC(O)R, and —OR, with the proviso that at least one of Y¹, Y², and Y³ is a curable group;
R is a C1-C4 alkyl group; and
n is at least 2 and m is at least 1, provided that the weight average molecular weight (M_{w}) of the reactive silicone additive is no more than 4200; and
(c) photo-acid generator.

2. The hardcoat composition of claim 1 comprising 15 wt. % or less of the reactive silicone additive based upon the total weight of the hardcoat composition.

3. The hardcoat composition of claim 2 comprising from 2 wt. % to 5 wt. % of the reactive silicone additive based upon the total weight of the hardcoat composition.

4. The hardcoat composition of claim 1 wherein the reactive silicone additive has a viscosity of 90 cSt or less at 25° C.

5. The hardcoat composition of claim 1 wherein the reactive silicone additive has the following general structure:
HO—Si(CH₃)₂—(O—Si(CH₃)₂)—OH (Formula 2a)
wherein M_{w} of the reactive silicone additive of Formula 2a is from 400 to 3500.

6. The hardcoat composition of claim 1 wherein the reactive silicone additive has the following general structure:
Z—SiMe₂-(O—SiMe₂)ₙ—OSiMe₂-Z (Formula 2b)
wherein M_{w} of the reactive silicone additive of Formula 2b is from 400 to 3500 and Z is selected from the group consisting of CH₃O—, CH₃CH₂O—, and (C₂H₆O)₃SiCH₂CH₂—.

7. The hardcoat composition of claim 1 wherein the epoxy silane compound is an epoxy-terminated silane compound.

8. The hardcoat composition of claim 7 wherein the epoxy silane compound is selected from the group consisting of γ-glicidoxypropyl trimethoxy silane, γ-glycidoxypropylmethyldiethoxysilane, and beta-(3,4-epoxycyclohexyl)ethyl-trimethoxysilane.

9. The hardcoat composition of claim 1 further comprising a compatibilizer, a leveling agent, a wetting agent, or a combination thereof.

10. The hardcoat composition of claim 1 further comprising (d) a curable fluorinated additive comprising a curable epoxide group or silane functionality or both.

11. The hardcoat composition of claim 10 wherein the curable fluorinated additive has the following general structure: 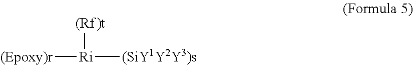
wherein, in Formula 5:
Ri is a multivalent radical of (r+s+t);
Epoxy is selected from and 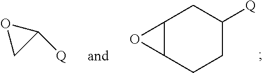
Q is a linkage group between the epoxy and Ri;
Rf is a perfluorinated alkyl group or perfluoropolyether group or a combination thereof;
t is at least 1;
(r+s) is at least 1; and
Y¹, Y², and Y³ are each independently selected from an alkyl group, aryl group, or hydrolyzable group, with the proviso that at least one of Y¹, Y², and Y³ is a hydrolyzable group.

12. The hardcoat composition of claim 1 wherein the composition is solventless or essentially solventless.

13. The hardcoat composition of claim 1 wherein the composition has a flash point of 140° F. or greater.

14. A hardcoat composition comprising the reaction product of:
(a) an epoxy silane compound,
(b) a reactive silicone additive having one of the following general structures: 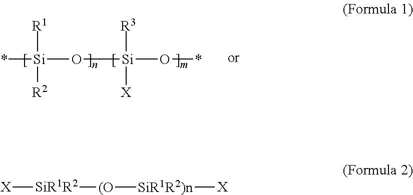
wherein:
R¹, R², and R³ are independently a C1-C6 alkyl group or aromatic group with or without substitution;
X is a curable group selected from —OH, —OR, —OC(O)R, —OSiY¹Y²Y³, —CH₂CH₂-L-SiY¹Y²Y³, and —C(OXR)₃, wherein:
L is a divalent linkage group;
Y¹, Y², and Y³ are independently selected from a C1-C6 alkyl group, and a curable group selected from —OH, —OC(O)R, and —OR, with the proviso that at least one of Y¹, Y², and Y³ is a curable group;
R is a C1-C4 alkyl group; and
n is at least 2 and m is at least 1, provided that the weight average molecular weight (M_{w}) of the reactive silicone additive is no more than 4200; and
(c) photo-acid generator.

15. The hardcoat composition of claim 14 comprising the reaction product of (a), (b), (c), and
(d) a curable fluorinated additive comprising a curable epoxide group or silane functionality or both.

16. The hardcoat composition of claim 15 wherein the curable fluorinated additive has the following general structure: 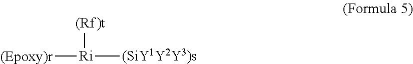
wherein, in Formula 5:
R1 is a multivalent radical of (r+s+t);
Epoxy is selected from and 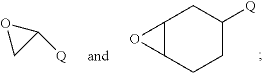
Q is a linkage group between the epoxy and Ri;
Rf is a perfluorinated alkyl group or perfluoropolyether group or a combination thereof;
t is at least 1;
(r+s) is at least 1; and
Y¹, Y², and Y³ are each independently selected from an alkyl group, aryl group, or hydrolyzable group, with the proviso that at least one of Y¹, Y², and Y³ is a hydrolyzable group.

17. The hardcoat composition of claim 15 wherein the composition is solventless or essentially solventless.

18. The hardcoat composition of claim 15 wherein the composition has a flashpoint of 140° F. or greater.

19. A coated article comprising a substrate and a protective layer comprising the cured hardcoat composition of claim 1 on at least a portion of the substrate.

20. A phototool comprising an optically clear substrate having a designed pattern, and a protective layer comprising the cured hardcoat composition of claim 1 on the substrate.
